(19) United States
(12) Patent Application Publication
(10) Pub. No.: US 2026/0254442 A1
(43) Pub. Date: Aug. 27, 2026

(54) CLOCK STRETCH COMPENSATION FOR DIGITAL FREQUENCY-LOCKED LOOP CIRCUITS

(71) Applicants: Advanced Micro Devices, Inc., Santa Clara, CA (US); ATI Technologies ULC, Markham (CA)

(72) Inventors: Sriram Sundaram, Santa Clara, CA (US); Arash Moghimi, Markham (CA); Ashish Jain, Santa Clara, CA (US); Shang Yang, Markham (CA)

(21) Appl. No.: 19/211,893

(22) Filed: May 19, 2025

Related U.S. Application Data
(60) Provisional application No. 63/763,700, filed on Feb. 26, 2025.

(51) Int. Cl. H03K 5/06; H03K 5/135; H03K 5/19

(52) U.S. Cl. CPC H03K 5/06; H03K 5/135; H03K 5/19

(57) ABSTRACT

An implementation is a processor including a voltage regulator configured to provide a supply voltage, a digital frequency-locked loop (DFLL) circuit having a stretch response configured to reduce an operating frequency in response to voltage droops in the supply voltage, and a clock stretch compensation (CSC) circuit. The CSC circuit being configured to monitor the operating frequency relative to a target frequency at a predetermined sampling rate, and increase the supply voltage based on a difference between the target frequency and the operating frequency.

### PRIORITY CLAIM

This application claims the benefit of U.S. Provisional Application No. 63/763,700, filed on February 26, 2025, which application is hereby incorporated herein by reference.

### BACKGROUND

Advanced processors utilize parallel processing architectures to perform numerous calculations simultaneously, enabling high-performance computing for various applications. These processors incorporate sophisticated power management techniques to balance performance and energy efficiency. This parallel approach allows for the distribution of computational tasks across numerous processing cores, enhancing overall system performance. By leveraging parallel processing, these processors can handle complex workloads efficiently, including graphics rendering, scientific simulations, and artificial intelligence algorithms.

### BRIEF DESCRIPTION OF THE DRAWINGS

For a more complete understanding of the present invention, and the advantages thereof, reference is now made to the following descriptions taken in conjunction with the accompanying drawings.

FIG. 1 illustrates a voltage-frequency graph showing an adaptive voltage frequency curve, in accordance with some implementations.

FIG. 2 illustrates a voltage-frequency graph with DFLL stretch response and load line effects, in accordance with some implementations.

FIG. 3 illustrates a voltage-frequency graph demonstrating clock stretch compensation, in accordance with some implementations.

FIG. 4 illustrates a voltage-frequency graph illustrating clock stretch compensation system operation, in accordance with some implementations.

FIG. 5 illustrates a flowchart of a Clock Stretch Compensation process, in accordance with some implementations.

FIG. 6 illustrates voltage and frequency responses during voltage droop events, in accordance with some implementations.

FIG. 7 illustrates a performance comparison graph of DFLL stretch response configurations, in accordance with some implementations.

FIG. 8 illustrates a block diagram of a processing system architecture, in accordance with some implementations.

Corresponding numerals and symbols in the different figures generally refer to corresponding parts unless otherwise indicated. The figures are drawn to clearly illustrate the relevant aspects of the implementations and are not necessarily drawn to scale. The edges of features drawn in the figures do not necessarily indicate the termination of the extent of the feature.

### DETAILED DESCRIPTION OF ILLUSTRATIVE IMPLEMENTATIONS

The making and using of various implementations are discussed in detail below. It should be appreciated, however, that the various implementations described herein are applicable in a wide variety of specific contexts. The specific implementations discussed are merely illustrative of specific ways to make and use various implementations and should not be construed in a limited scope.

Reference to “an implementation” or “one implementation” in the framework of the present description is intended to indicate that a particular configuration, structure, or characteristic described in relation to the implementation is included in at least one implementation. Hence, phrases such as “in one implementation” that may be present in one or more points of the present description do not necessarily refer to one and the same implementation. Moreover, particular conformations, structures, or characteristics may be combined in any adequate way in one or more implementations. The references used herein are provided merely for convenience and hence do not define the extent of protection or the scope of the implementations.

Clock Stretch Compensation (CSC) is designed to address the challenge of maintaining optimal performance in modern processors while mitigating voltage instability. In various processor types, including graphics processing units (GPUs), accelerated processing units (APUs), central processing units (CPUs), and specialized cores such as intelligence processing units (IPUs), sudden increases in power demand may result in temporary voltage reductions, referred to as voltage droop events. These events may cause the processor's clock to slow down or become unstable, potentially leading to errors or reduced performance.

To comprehend the functionality of CSC, it is essential to first understand the concept of a Digital Frequency-Locked Loop (DFLL). A DFLL is a system that maintains a stable clock frequency in a processor by continuously monitoring the processor's voltage and adjusting the clock frequency to ensure stable operation. However, when faced with rapid voltage fluctuations, a DFLL alone may be insufficient to maintain both stability and performance.

CSC operates in conjunction with the DFLL to provide a more refined approach to managing voltage droop events. When a voltage droop occurs, CSC temporarily permits a reduction in clock frequency to prevent instability. However, unlike a system utilizing only a DFLL, CSC actively counteracts this frequency reduction by applying a voltage offset. This offset helps bring the operating point closer to the processor's ideal voltage-frequency curve, enabling improved performance while maintaining protection against voltage droop events. CSC addresses the balance between performance and stability. Without CSC, processors would be required to operate at lower frequencies to avoid instability during voltage droops or risk errors during these events. CSC enables the processor to operate at higher frequencies most of the time while still protecting against the negative effects of voltage droops.

CSC provides benefits in practical applications. Experimental results have demonstrated that CSC can yield performance improvements of 1-2% across various power levels. While this improvement may appear modest, in the context of high-performance computing, even small improvements can result in substantial gains in real-world applications. CSC achieves these improvements through dynamic adjustment of the processor's voltage and frequency in response to changing conditions. It continuously monitors the difference between the target frequency and the actual operating frequency, as well as the difference between the target voltage and the actual supply voltage. Based on these measurements, CSC calculates and applies voltage offsets to optimize performance while maintaining stability.

In implementing CSC, system designers should consider the impact on Electrical Design Current (EDC). The addition of voltage offsets to compensate for clock stretching can increase the current draw of the system. However, experimental results have shown that even with increased EDC throttling, the performance benefits of CSC remain substantial, typically yielding 2-2.5% performance uplift. This performance improvement comes from the system's ability to maintain higher operating frequencies while still protecting against voltage droop events. The EDC increase, while measurable, does not significantly detract from these performance gains in typical operating conditions.

By enabling processors to operate closer to their theoretical limits while still providing robust protection against voltage fluctuations, CSC contributes to the ongoing advancement of processor technology across a wide range of applications.

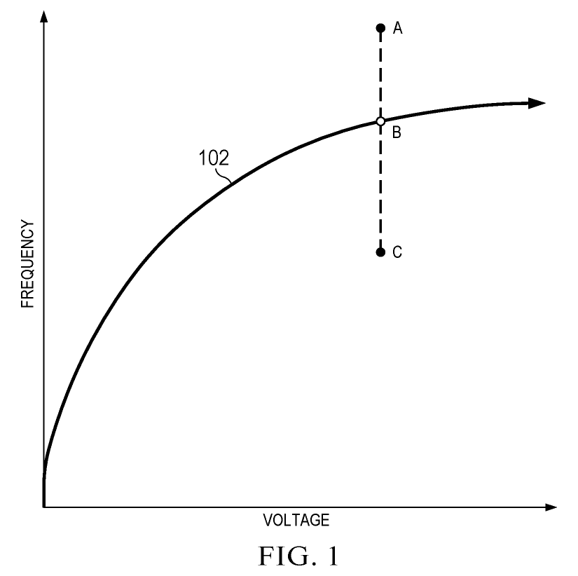

FIG. 1 illustrates an adaptive voltage frequency scaling (AVFS) curve according to various implementations. In FIG. 1, an AVFS curve 102 shows the relationship between operating voltage and operating frequency in a device, such as a semiconductor device. The y-axis of the graph represents the operating frequency, while the x-axis represents the operating voltage. In some implementations, the AVFS curve 102 exhibits a non-linear shape, with a steeper slope at lower frequencies and voltages that gradually levels off at higher frequencies and voltages.

The AVFS curve 102 may be considered a boundary between valid and invalid operating points for the device. A valid operating point C is shown below the AVFS curve 102, representing a stable but inefficient combination of voltage and frequency as the frequency is lower than necessary for the given voltage. In contrast, an invalid operating point A is depicted above the AVFS curve 102, indicating a combination of voltage and frequency that may lead to timing failures or instability in the device. A target operating point B is illustrated on the AVFS curve 102, representing an ideal operating condition that balances performance and power efficiency.

Operating on or near the AVFS curve 102 is beneficial for achieving optimal performance and efficiency in the device. By maintaining operation close to the curve, the device can operate at the lowest possible voltage for a given frequency, which may help minimize power consumption while maintaining stability. This relationship between voltage and frequency can be utilized by a processor that includes a voltage regulator configured to provide a supply voltage and a digital frequency-locked loop (DFLL) circuit configured to adjust an operating frequency based on the supply voltage.

In some cases, operating points below the AVFS curve 102 may also be considered valid, as they provide additional voltage margin for stability. However, operating too far below the curve may result in unnecessary power consumption. Conversely, operating points above the curve may lead to timing violations and functional failures in the device.

The AVFS curve 102 may serve as a guide for dynamic voltage and frequency scaling in the semiconductor device. As the device's workload changes, the operating point may be adjusted along the curve to balance performance requirements with power efficiency. This dynamic scaling may be particularly useful in modern processors that need to adapt to varying computational demands while managing power consumption.

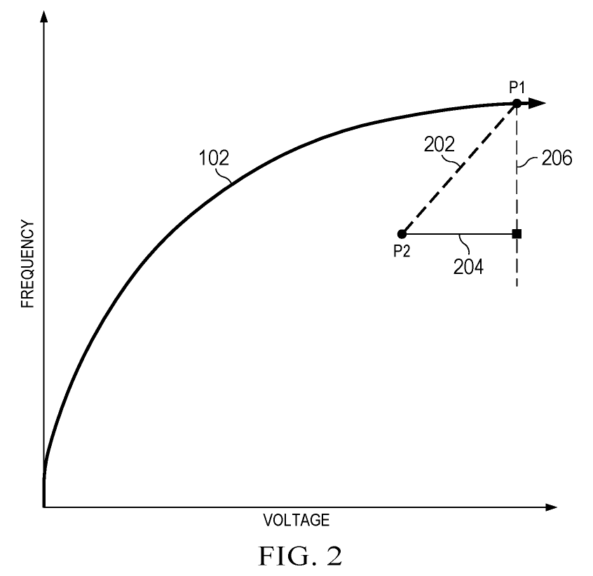

FIG. 2 illustrates a voltage-frequency graph depicting a Digital Frequency-Locked Loop (DFLL) stretch response and load line effects according to various implementations. The graph in FIG. 2 includes the AVFS curve 102 and a DFLL stretch response 202, representing the system's dynamic adjustment of operating frequency in response to voltage changes. Two points are shown on the graph: P1, which represents the target operating point, and P2, which represents the actual operating point after accounting for load line effects and the DFLL stretch response.

The DFLL stretch response 202 is configurable, allowing its steepness to be modified based on the specific needs or requirements of the device. A steeper DFLL stretch response can quickly reduce the operating frequency during DiDt events, which are rapid changes in current demand that can lead to voltage fluctuations, thus maintaining system stability and preventing functional failures. However, a steeper response may also result in a greater deviation from the optimal operating frequency during normal conditions, potentially leading to performance loss. Conversely, a shallower stretch response may maintain closer adherence to the optimal frequency under normal conditions but may not react swiftly enough to mitigate rapid voltage drops during DiDt events.

The set voltage 204 shown in the graph illustrates the effects of load line on the system's operating point. Load line effects refer to the voltage drop that occurs between the voltage regulator output and the actual voltage at the processor pins due to parasitic resistance and other inefficiencies in the power delivery network. As a result of these load line effects, the actual operating voltage at point P2 is lower than the target voltage 206 set by the system, shown to the left in the graph. This shift in operating point due to load line effects aids in understanding the system's performance under varying electrical conditions.

In FIG. 2, the difference between the target voltage 206 and the set voltage 204 demonstrates how load line effects impact the system's operating point. The system may target an operating point at the intersection of the target voltage 206 and the AVFS curve 102 (e.g., target operating point P1). However, due to load line effects, the actual operating point shifts to a lower voltage and frequency, as indicated by the intersection of the set voltage 204 and the DFLL stretch response 202 (e.g., stretched operating point P2).

The interactions between the DFLL stretch response 202, DiDt events, and load line effects influence overall system performance. The DFLL stretch response 202 helps maintain system stability during DiDt events by quickly reducing frequency when voltage drops occur, and this protective stretch response during actual droop events is intentionally preserved by the system. However, during typical operation (outside of droop events), load line effects cause a voltage drop between the regulator output and the processor pins, which results in unnecessary frequency reduction due to the steep DFLL stretch response. This continuous load line-induced frequency reduction leads to performance loss, as the system operates at a lower frequency than initially targeted. Clock stretch compensation (CSC) is specifically designed to address this performance loss during typical operation by compensating for load line effects, while intentionally preserving the full DFLL stretch response during actual voltage droop events. Without CSC, the combination of load line effects and steep DFLL response results in the system operating at a point that may be significantly below the optimal voltage-frequency relationship defined by the AVFS curve 102 during normal operation.

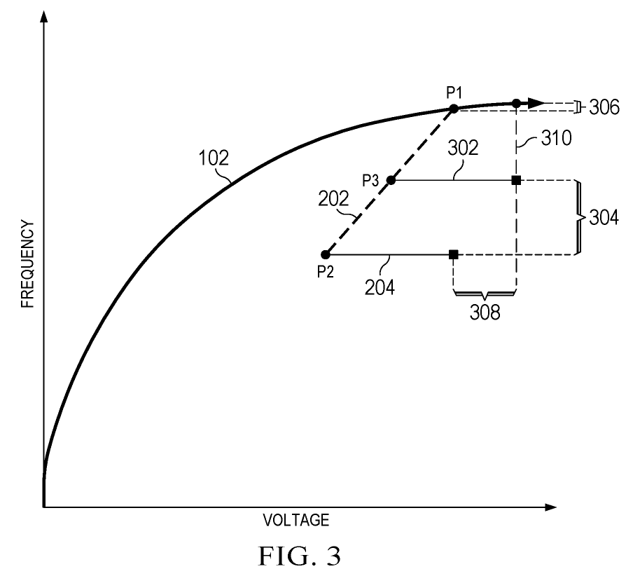

In some implementations, the processor may include a clock stretch compensation (CSC) circuit configured to detect a voltage droop in the supply voltage. The CSC circuit may monitor the supply voltage and identify when it drops below a certain threshold, indicating a voltage droop event. By detecting these voltage droops, the CSC circuit can initiate compensatory actions to mitigate their impact on system performance. Implementations of systems incorporating CSC are illustrated in FIGS. 3-5, which demonstrate how CSC can be applied to address the challenges presented by DFLL stretch response and load line effects.

The DFLL stretch response 202 and load line effects illustrated in FIG. 2 provide insight into the challenges faced in maintaining optimal performance while ensuring system stability in modern processors. These factors underscore the need for advanced compensation techniques, such as CSC, to balance performance and reliability in graphics processing systems and other high-performance computing applications. FIGS. 3-5 further explore how CSC can be implemented to address these challenges and optimize system performance.

FIG. 3 illustrates a voltage-frequency graph depicting the operation of a Clock Stretch Compensation (CSC) system according to various implementations. CSC aims to optimize processor performance by adjusting voltage levels in relation to the AVFS curve 102. As discussed in FIG. 2, without CSC, the processor may operate at stretched operating point P2, which is at the intersection of the DFLL stretch response 202 and the set voltage 204. This suboptimal operating point may result in reduced performance due to clock stretching and load line effects.

Load line effects, which cause voltage drops between the voltage regulator output and the processor pins, are evident in the difference between the target voltage at point P1 and the pin voltage at point P2. Load line effects also contribute to the frequency reduction from point P1 to point P2.

CSC improves the operating point by applying a voltage offset to increase the supply voltage, compensating for load line effects and other factors that may reduce performance. This adjustment is represented by the set voltage 302, which brings the operating point closer to the AVFS curve 102. In FIG. 3, the dot at the right end of 302 represents the set voltage, which in the CSC case (P3) is positioned to the right of the target voltage at P1. By operating closer to the ideal curve, the processor may achieve higher frequencies without experiencing the load line-induced clock stretching that occurs during normal operation. This is important because the system still maintains full DFLL clock stretching capability during actual voltage droop events for protection.

The difference between the set voltage (with CSC) 302 and the set voltage (no CSC) 204 is referred to as a voltage offset 308. The voltage offset 308 represents the additional voltage offset provided by CSC to counteract load line effects and other voltage drops. This additional voltage can help to maintain stability while maximizing performance.

As a result of the CSC adjustment, a performance uplift 304 may be achieved. This performance uplift 304 represents the improvement in processor performance compared to the performance that would occur without CSC, taking into account both the initial performance reduction due to load line effects and the subsequent frequency reduction caused by the DFLL stretch response 202. FIG. 3 illustrates that increasing the target frequency from P1 higher up on the AVFS curve (as shown 306)) would not provide as much frequency uplift as adding voltage margin to reduce stretch (as shown by 304). In some implementations, the performance uplift may be in the range of 1-2% across various power levels.

In some implementations, CSC operates on a 1 millisecond cadence, continuously monitoring and adjusting the voltage offset as needed. This frequent adjustment allows the processor to adapt to changing workloads and operating conditions, maintaining optimal performance over time.

A target voltage 310 is established as part of the CSC operation. The CSC circuit may be configured to determine a voltage offset based on load line effects, applying this offset to increase the supply voltage above a nominal voltage level. This approach may counteract performance loss caused by load line effects reducing the DFLL’s frequency, allowing the processor to maintain higher performance levels while still protecting against potential instability.

By implementing the CSC feature, processors may operate closer to their theoretical performance limits while maintaining robust protection against voltage fluctuations and compensating for load line effects. This balance between performance and stability may contribute to improved overall system efficiency and responsiveness across a wide range of applications.

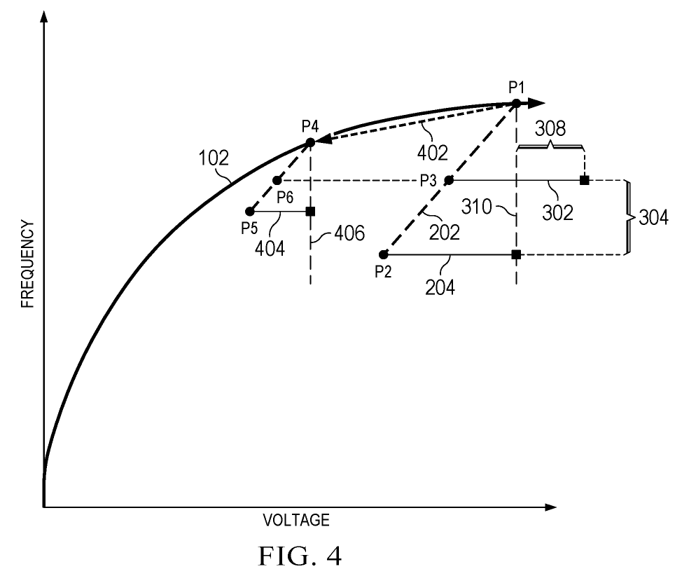

FIG. 4 illustrates a voltage-frequency graph depicting the operation of a CSC system according to various implementations. The graph in FIG. 4 shows the progression of operating points as the CSC system responds to voltage droops and compensates for performance loss. FIG. 4 is similar to FIG. 3 but adds further details about the adjustment of the frequency by a power management controller to P4 after the initial CSC adjustment. Unlike FIG. 3, in FIG. 4 all comparisons are made relative to VSET, so the baseline is shifted to P1 rather than using a separate reference point. Details of the previous implementation that are similar in this implementation are not repeated herein.

The CSC system begins operation at a target operating point P1, which represents the ideal operating condition on the AVFS curve 102. However, due to load line effects and the DFLL's response to voltage droops, the system may initially operate at a stretched operating point P2. This point is located on the DFLL stretch response 202 curve and represents a lower frequency and voltage than the target operating point P1.

To counteract this performance loss, the CSC system calculates a frequency delta between the target frequency (at P1) and the actual operating frequency (at P2). The CSC circuit may then compare this frequency delta against a predetermined threshold. If the frequency delta exceeds this threshold, it may trigger the compensation process. In some cases, the CSC circuit may be configured to determine a voltage offset based on this calculated frequency delta. The system then applies this voltage offset, moving the operating point to a compensated stretch operating point P3. In FIG. 4, the dot at the right end of 302 and P3 represents the set voltage with CSC applied, which is positioned to the right of P1, indicating the additional voltage margin added to reduce stretch.

At the compensated stretch operating point P3, the system operates at a higher voltage than P2, which allows for a higher frequency while still maintaining protection against voltage droops. The difference between the set voltage (no CSC) 404 and the set voltage (with CSC) 302 represents the voltage offset applied by the CSC system.

In addition to the frequency delta, the CSC circuit may also calculate a voltage delta between a target voltage and the supply voltage. This voltage delta may also be compared against a separate threshold to determine if compensation is necessary. In some implementations, the CSC circuit may be configured to determine the voltage offset based on both the calculated frequency delta and the calculated voltage delta, but only if one or both of these deltas exceed their respective thresholds. This dual consideration, along with the threshold checks, allows for more precise and controlled compensation, ensuring that the CSC system only activates when truly needed.

As the system continues to operate with the applied voltage offset, the power management system may detect the increased power consumption and adjust the target frequency. This adjustment is represented by the frequency adjustment 402, which moves the target operating point from P1 to an adjusted target operating point P4.

The DFLL may then respond to this new target, potentially resulting in an adjusted stretch operating point P5. At this point, the CSC system may recalculate the frequency and voltage deltas. In some implementations, threshold-based adjustments may be used to determine if further compensation is necessary.

Regardless of the specific approach, the CSC system applies the determined voltage offset, bringing the system to a compensated stretch operating point P6.

The performance uplift 304 illustrates the frequency improvement achieved through the CSC process. By comparing the initial stretched operating point P2 with the compensated stretch operating point P6, the graph demonstrates the performance gains made possible by the CSC system. The specific gains may vary depending on the particular operating conditions.

Throughout this process, the CSC system may continuously monitor and adjust the voltage offset to maintain an optimal balance between performance and protection against voltage droops. The voltage offset 308 between the target voltage 310 and the actual supply voltage is used to fine-tune the compensation, ensuring that the system operates as close to the AVFS curve 102 as possible while still maintaining the necessary voltage margins for stability.

In some implementations, the CSC system may also consider a second target voltage 406, which could represent an upper limit for voltage compensation or an alternative operating point for different power states. This flexibility allows the CSC system to adapt to various operating conditions and power management strategies.

The CSC system's ability to dynamically adjust voltage offsets based on both frequency and voltage deltas enables processors to operate closer to their theoretical performance limits while maintaining robust protection against voltage fluctuations. This approach contributes to improved overall system performance and efficiency across a wide range of applications and workloads.

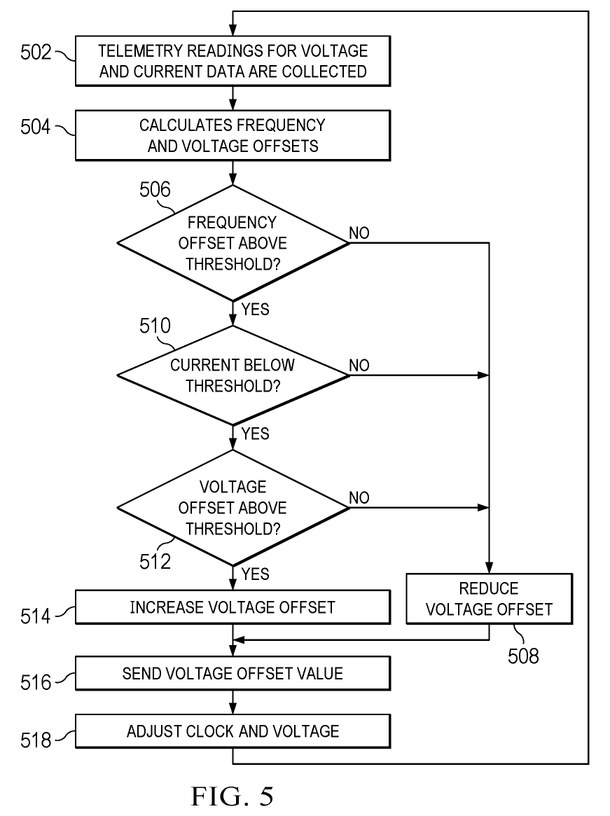

FIG. 5 illustrates a flowchart for a clock stretch compensation process according to various implementations. The clock stretch compensation process begins at a step 502, where a processor collects voltage and current telemetry data (typically at a 1 millisecond cadence). This data may include telemetry information about the current operating conditions of the processing system 800.

At a step 504, the microcontroller calculates frequency and voltage offsets. In some cases, these calculations may involve determining two variables: fDelta and vDelta. The fDelta may represent the difference between the target frequency and the pre-deep sleep frequency, which is essentially the actual operating frequency after accounting for any frequency stretching. The vDelta may represent the difference between the set voltage and the voltage read back through telemetry, which accounts for load line effects and other factors affecting the actual supply voltage.

The process then flows to a decision block 506, which checks if the frequency offset (fDelta) is above a threshold. This threshold may be predetermined based on system requirements and performance goals but may be set to 0 to indicate all stretching must be eliminated. If the frequency offset is not above the threshold (N branch), the process moves to a step 508 where the voltage offset is reduced. This reduction may help optimize power consumption when frequency compensation is not needed.

If the frequency offset is above the threshold (Y branch), the process continues to a decision block 510. This decision block determines if the stretch modulation features are below a threshold. This threshold may be set to prevent a positive feedback loop occurring between features that stretch clock to mitigate DiDt or EDC and the CSC feature. If the activation residency of these stretch modulation features is not below the threshold (N branch), the process moves to the step 508 to reduce the voltage offset.

If the residency is below the threshold (Y branch), the process continues to a decision block 512, which checks if the voltage offset is above a threshold. This check may ensure that the applied voltage offset stays within safe operating limits. If the voltage offset is not above the threshold (N branch), the process moves to the step 508 to reduce the voltage offset.

If the voltage offset is above the threshold (Y branch), the process proceeds to a step 514 where the voltage offset is increased. In some implementations, the CSC circuit may be configured decrease the voltage offset when the voltage delta is below a first threshold, provide no offset when it is between the first and second thresholds and increase it when it’s higher than a second threshold. This approach may help balance performance improvements with power efficiency.

Following either the step 508 or the step 514, the process moves to a step 516 where the voltage offset value is sent. This step may involve communicating the calculated voltage offset to the appropriate power management components within the processing system 800.

The process then continues to a step 518 where the clock and voltage are adjusted based on the sent voltage offset value. In some cases, the CSC circuit may be configured to apply the voltage offset in a stepwise manner over a predetermined time period. This gradual application of the voltage offset may help maintain system stability during the compensation process.

After the step 518, the process loops back to the step 502, where new voltage and current data are sent to the microcontroller. This continuous loop allows the CSC system to adapt to changing operating conditions and maintain optimal performance over time.

The clock stretch compensation process illustrated in FIG. 5 may provide a dynamic approach to managing voltage and frequency in the processing system 800. By continuously monitoring and adjusting these parameters, the system may maintain a balance between performance and power efficiency while protecting against voltage droop events.

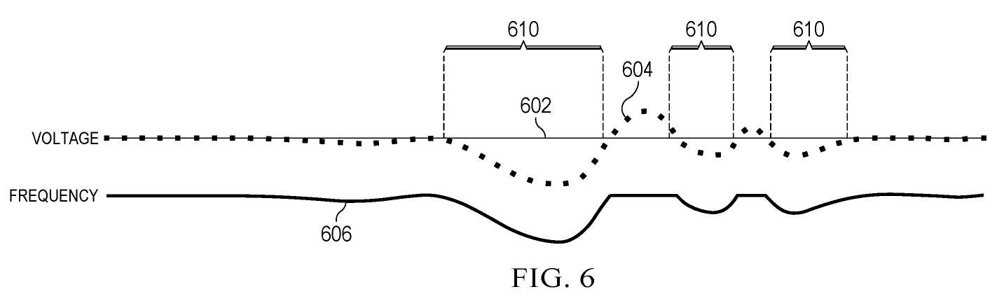

FIG. 6 illustrates voltage and frequency responses during voltage droop events according to various implementations. FIG. 6 depicts the behavior of a voltage reference 602, a voltage signal 604, and a frequency 606. The voltage reference 602 represents the target voltage level for the system, while the voltage signal 604 shows the fluctuations in voltage. The frequency 606 illustrates how the system's clock speed responds to these voltage changes.

At the beginning of the droop time period 610, the voltage reference 602 may be stable at a nominal level. This stable voltage allows the system to operate at its target frequency. However, as the droop time period 610 progresses, multiple voltage droop events occur.

When a voltage droop event begins, the voltage signal 604 may rapidly decrease below the voltage reference 602 level. The magnitude and duration of each voltage droop may vary depending on the specific conditions causing the event. In some cases, the voltage signal may recover quickly, returning to the voltage reference 602 level. In other cases, the recovery may be more gradual.

The frequency 606 response to these voltage droop events may be closely tied to the voltage signal 604 changes. As the voltage signal 604 drops during a voltage droop event, the frequency 606 may decrease to maintain system stability. This reduction in frequency may help prevent timing violations that could occur if the system attempted to maintain its original clock speed at a lower voltage.

The temporal relationship between the voltage signal 604 and the frequency 606 response may be nearly instantaneous. The DFLL circuit may quickly adjust the operating frequency based on the detected voltage changes. This rapid response may be crucial for maintaining system stability during voltage fluctuations.

Throughout the droop time periods 610, the system may demonstrate a pattern of voltage droops followed by frequency adjustments. As the voltage recovers from a droop event, the frequency may increase again, potentially returning to its original level if the voltage fully recovers to the voltage reference 602.

In some cases, the CSC circuit may play a role in managing these voltage and frequency fluctuations. The CSC circuit may be configured to determine a voltage offset based on the detected frequency stretching caused by load line effects during normal operation. While additional voltage margin may help with mitigating droop events, the primary purpose of this voltage offset is to counteract the performance loss caused by load line-induced frequency stretching. The CSC feature preserves the protective DFLL stretch response during actual voltage droop events while improving performance during normal operation.

The system management unit (SMU) may monitor the supply voltage and provide voltage telemetry data to the CSC circuit. This telemetry data may be used in the CSC circuit's decision-making process. In some implementations, the CSC circuit may be configured to determine the voltage offset based on the voltage telemetry data provided by the SMU at a predetermined sampling rate.

By continuously monitoring and responding to voltage fluctuations, the system may maintain a balance between performance and stability. The interplay between voltage and frequency, as illustrated in FIG. 6, may demonstrate the system's ability to adapt to changing power conditions while striving to maintain optimal operation.

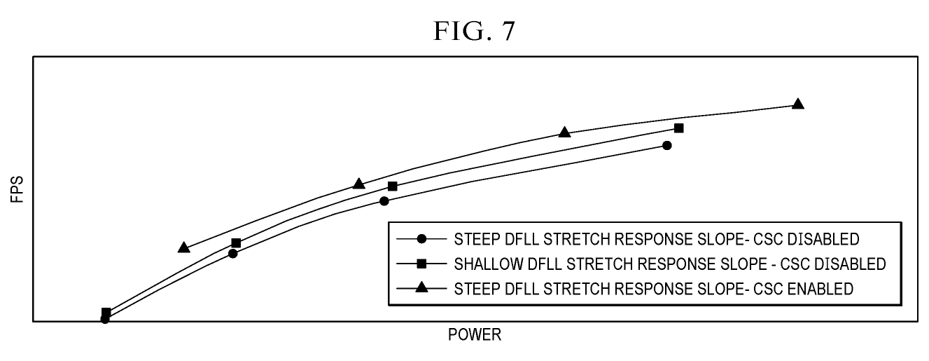

FIG. 7 illustrates a performance comparison graph showing frames per second (FPS) versus power consumption for different DFLL stretch response configurations according to various implementations.

The graph in FIG. 7 depicts three distinct curves representing different operating modes: a steep DFLL stretch response slope with CSC disabled, a shallow DFLL stretch response slope with CSC disabled, and a steep DFLL stretch response slope with CSC enabled. These curves demonstrate increasing FPS as power consumption increases, allowing for a comprehensive comparison of performance across various power levels and configurations.

The steep DFLL stretch response slope with CSC disabled shows the baseline performance. This configuration may provide robust protection against voltage droop events but may result in lower overall performance due to aggressive frequency reduction during normal operation.

In contrast, the shallow DFLL stretch response slope with CSC disabled demonstrates improved performance compared to the steep slope without CSC. This configuration may allow for higher operating frequencies during normal conditions but may offer less protection against voltage droop events.

The steep DFLL stretch response slope with CSC enabled consistently achieves higher performance across the entire power range compared to both CSC-disabled configurations. This performance improvement may be attributed to the CSC feature's ability to counteract the frequency reduction caused by the steep DFLL slope while maintaining protection against voltage droop events.

The performance benefits of CSC-enabled operation become more pronounced as power consumption increases. At lower power levels, the CSC-enabled configuration shows a modest improvement over the shallow slope configuration without CSC. However, as power consumption rises, the performance gap widens, with the CSC-enabled configuration maintaining a significant advantage over both CSC-disabled configurations. Performance uplift will correlate with steepness of the DFLL slope - the steeper the DFLL stretch response slope, the more performance uplift will be observed when CSC is enabled.

In some cases, the CSC feature may increase Electrical Design Current (EDC). This increase in current draw may be a trade-off for the improved performance, as the system may operate at higher voltages to compensate for potential frequency reductions. However, the performance gains achieved through CSC may outweigh the increased power consumption in many scenarios.

It may be noted that the CSC feature may not provide protection at high voltages close to VMAX due to lack of additional headroom. As the operating voltage approaches VMAX, the ability to apply voltage offsets may be limited, potentially reducing the effectiveness of CSC in these high-voltage scenarios.

The CSC feature may be more effective for graphics workloads with consistent frame-by-frame submissions compared to bursty compute workloads. Graphics workloads often exhibit more predictable power consumption patterns, allowing the CSC algorithm to make more accurate voltage offset calculations. In contrast, bursty compute workloads with varying power demands may present challenges for the CSC feature to maintain optimal performance consistently.

In some implementations, the CSC feature may cause the Power and Performance Tuning (PPT) controller to take longer to arrive at a steady state. This extended settling time may be due to the dynamic nature of CSC adjustments, which may introduce additional variables for the PPT controller to consider when optimizing power and performance.

The performance comparison illustrated in FIG. 7 demonstrates the potential benefits of implementing CSC in systems with steep DFLL stretch responses. By enabling CSC, processors may achieve higher performance levels across various power consumption ranges while maintaining protection against voltage droop events. This approach may contribute to improved overall system efficiency and responsiveness in a wide range of applications and workloads.

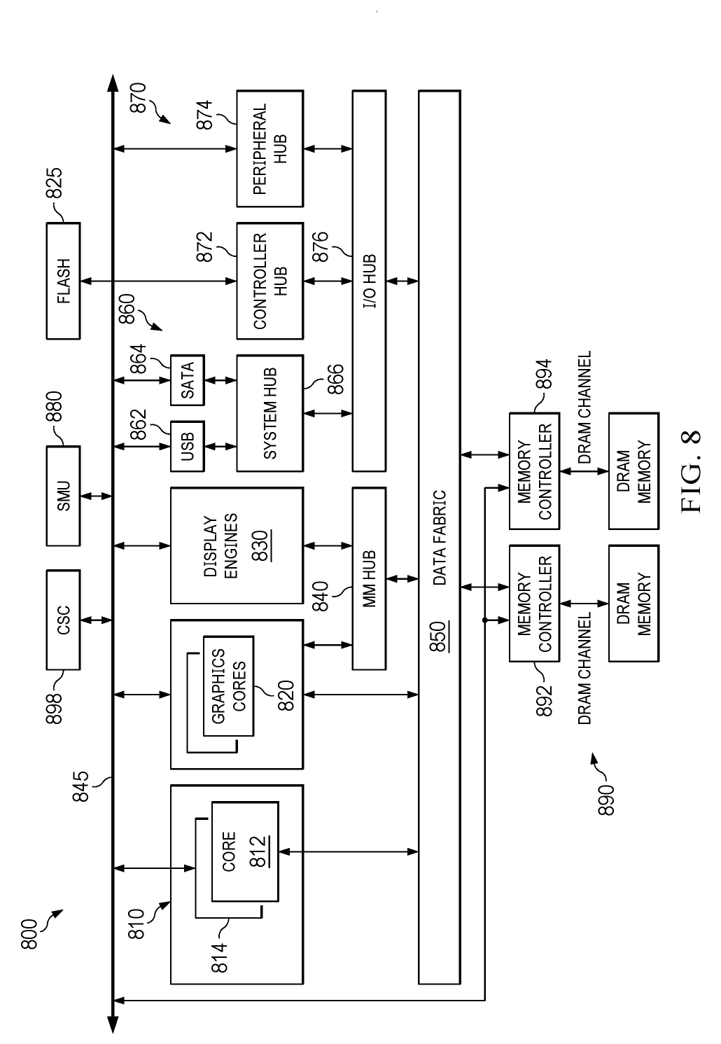

FIG. 8 illustrates a block diagram of a processing system architecture 800 according to various implementations. The processing system 800 may comprise a comprehensive architecture designed to support various computing tasks, including graphics processing and system management. This system may be implemented as a System-on-Chip (SoC) suitable for various host data processing platforms, such as an accelerated processing unit (APU), central processing unit (CPU), graphics processing unit (GPU), or specialized processor cores like intelligence processing units (IPUs).

A processor block 810 may form a central part of the processing system 800. The processor block 810 may include one or more processor cores 812 and a processor interface 814. In some implementations, the processor block 810 may include multiple processor tiles, each containing one or more CPU cores. The processor core 812 may execute instructions and perform calculations, including clock stretch compensation algorithms, while the processor interface 814 may facilitate communication between the processor core 812 and other components of the system.

Graphics cores 820 may be included in the processing system 800 to handle graphics-intensive tasks. These graphics cores 820 may implement the AVFS curve 102, DFLL stretch response 202, and other elements described in earlier figures. They may work in conjunction with display engines 830 to render and output visual information. The display engines 830 may manage the final stages of graphics processing, including rendering and rasterizing objects for output to display devices.

A memory management hub 840 may coordinate data flow between various components of the processing system 800. This memory management hub 840 may be connected to other components through an interconnect path 845, which may serve as a high-speed data highway within the system.

A data fabric 850 may provide a flexible and scalable interconnection network for the processing system 800. The data fabric 850 may allow efficient communication between different components, potentially improving overall system performance. It may include a crossbar switch for routing memory access requests and responses between memory accessing agents and memory controllers.

The processing system 800 may include several interfaces for external connectivity. A display interface 860 may allow connection to external display devices. A USB interface 862 and a SATA interface 864 may provide standardized connections for peripherals and storage devices, respectively.

A system hub 866 may act as a central connection point for various system components. The system hub 866 may connect to a controller hub 872 and a peripheral hub 874 through an interface path 870. An input output hub 876 may manage data flow between these hubs and other system components.

Flash memory 825 may be included in the processing system 800 to provide non-volatile storage for system firmware and other critical data. This flash memory 825 may store instructions that, when executed by the processor core 812, cause the processor to perform operations for compensating clock stretch.

A system management unit (SMU) 880 may play a role in implementing the Clock Stretch Compensation (CSC) feature. The SMU 880 may monitor system voltages and provide telemetry data to other components involved in the CSC process. In some cases, the SMU 880 may implement the CSC feature through firmware changes. The SMU 880 may also control the operation of resources on the system, manage power-up sequencing, and control multiple off-chip devices via reset, enable, and other signals.

In some implementations, a CSC circuit 898 may be included in the system to implement the CSC features. The CSC circuit 898 may include a first input configured to receive voltage telemetry data from a SMU 880 and a second input configured to receive frequency data indicating an operating frequency of a digital frequency-locked loop (DFLL) circuit. The CSC circuit 898 may also include control logic configured to detect a reduction in the operating frequency caused by a stretch response of the DFLL circuit, and output a control signal to increase a supply voltage based on the detected reduction.

The processing system 800 may include memory controllers to manage system memory. A first memory controller 890 may connect to memory through a first DRAM channel 892. A second memory controller 894 may provide additional memory management capabilities, potentially allowing for expanded memory capacity or improved memory performance. The memory subsystem may store various parameters and data required for implementing the clock stretch compensation techniques.

The CSC feature/circuit 898 may be integrated into the processing system 800 through interactions between the SMU 880, the processor core 812, and other system components. The SMU 880 may continuously monitor voltage levels and provide this data to the processor core 812. The processor core 812 may then execute instructions stored in the flash memory 825 to perform CSC operations, adjusting voltage offsets as needed to maintain optimal performance.

In some implementations, a voltage regulator may be integrated within the processor block 810, graphics cores 820, or may be an external component connected to the system. This voltage regulator may adjust the voltage supplied to the graphics cores 820 based on the offset information calculated by the compensation system.

By incorporating the CSC feature/circuit 898, the processing system 800 may achieve improved performance and stability. The CSC feature/circuit 898 may allow the system to operate at higher frequencies while still protecting against voltage droop events, potentially resulting in better overall system efficiency and responsiveness across a wide range of applications, including graphics-intensive tasks.

The system may support either a unified memory architecture where CPU and GPU components share the same memory space, or a mixed architecture where they share a portion of the memory space while the GPU also uses private graphics memory.

The CSC feature/circuit 898 provides a sophisticated approach to managing voltage and frequency in graphics processing systems. CSC continuously monitors voltage levels and adjusts clock frequencies to maintain optimal performance while protecting against voltage droop events. By applying voltage offsets, CSC allows processors to operate closer to their ideal voltage-frequency curves, potentially improving performance by 1-2% across various power levels.

CSC addresses the challenge of balancing high performance with system stability in modern graphics processing units. Without CSC, processors may need to operate at lower frequencies to avoid instability during voltage droops, or risk errors during these events. CSC enables processors to run at higher frequencies most of the time while still maintaining protection against voltage fluctuations.

The dynamic nature of CSC allows it to adapt to changing workloads and operating conditions. By continuously calculating and applying voltage offsets based on real-time measurements of frequency and voltage deltas, CSC provides a flexible solution that can be implemented across various processor architectures. This approach contributes to improved overall system efficiency and responsiveness in a wide range of applications and workloads.

In an implementation, a processor includes a voltage regulator configured to provide a supply voltage, a digital frequency-locked loop (DFLL) circuit having a stretch response configured to reduce an operating frequency in response to voltage droops in the supply voltage, and a clock stretch compensation (CSC) circuit configured to monitor the operating frequency relative to a target frequency at a predetermined sampling rate, and increase the supply voltage based on a difference between the target frequency and the operating frequency.

The described implementations may also include one or more of the following features. The CSC circuit is further configured to calculate a frequency delta between the target frequency and the operating frequency, and increase the supply voltage based on the calculated frequency delta. The CSC circuit is further configured to calculate a voltage delta between a target voltage and the supply voltage, and increase the supply voltage based on both the calculated frequency delta and the calculated voltage delta. The CSC circuit is configured to increase the supply voltage when the voltage delta is above a threshold. The CSC circuit is configured to increase the supply voltage in a stepwise manner over a predetermined time period. The processor further includes a system management unit (SMU) configured to monitor the supply voltage and provide voltage telemetry data to the CSC circuit. The predetermined sampling rate corresponds to a rate at which the SMU provides the voltage telemetry data to the CSC circuit.

In an implementation, a method for compensating clock stretch in a processor, includes receiving voltage telemetry data indicating voltage droops in a supply voltage, detecting, based on the voltage telemetry data, a reduction in an operating frequency by a digital frequency-locked loop (DFLL) circuit having a stretch response slope, and increasing the supply voltage based on a difference between the operating frequency and a target frequency to counteract frequency reduction caused by the DFLL circuit's stretch response slope.

The described implementations may also include one or more of the following features. The method further includes calculating a frequency delta between the target frequency and the operating frequency, and increasing the supply voltage based on the calculated frequency delta. The method further includes calculating a voltage delta between a target voltage and the supply voltage, and increasing the supply voltage based on both the calculated frequency delta and the calculated voltage delta. Increasing the supply voltage occurs when the voltage delta is above a threshold. The voltage telemetry data is received from a system management unit (SMU) at a predetermined sampling rate. The predetermined sampling rate is one millisecond. The stretch response slope of the DFLL circuit is steeper than an adaptive voltage frequency scaling (AVFS) curve of the processor.

In an implementation, a clock stretch compensation (CSC) circuit for a processor, includes a first input configured to receive voltage telemetry data from a system management unit (SMU), a second input configured to receive frequency data indicating an operating frequency of a digital frequency-locked loop (DFLL) circuit, and control logic configured to detect a reduction in the operating frequency caused by a stretch response of the DFLL circuit, and output a control signal to increase a supply voltage based on the detected reduction.

The described implementations may also include one or more of the following features. The voltage telemetry data is received from the SMU at a predetermined sampling rate of one millisecond, and the control signal is output at the predetermined sampling rate. The control logic is further configured to calculate a frequency delta between a target frequency and the operating frequency, and calculate a voltage delta between a target voltage and the supply voltage indicated by the voltage telemetry data. The control logic is configured to output the control signal to increase the supply voltage when the voltage delta is above a threshold voltage value. The control logic is configured to compare the operating frequency to an adaptive voltage frequency scaling (AVFS) curve, and output the control signal to increase the supply voltage to bring the operating frequency closer to the AVFS curve. The control logic is configured to continue outputting the control signal to increase the supply voltage until a maximum voltage threshold is reached.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular implementations described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding implementations described herein. Accordingly, the appended claims are intended to include within their scope such processes, machines, manufacture, compositions of matter, means, methods, or steps.

What is claimed is:

1. A processor, comprising:
a voltage regulator configured to provide a supply voltage;
a digital frequency-locked loop (DFLL) circuit having a stretch response configured to reduce an operating frequency in response to voltage droops in the supply voltage; and
a clock stretch compensation (CSC) circuit configured to:
monitor the operating frequency relative to a target frequency at a predetermined sampling rate; and
increase the supply voltage based on a difference between the target frequency and the operating frequency.

2. The processor of claim 1, wherein the CSC circuit is further configured to:
calculate a frequency delta between the target frequency and the operating frequency; and
increase the supply voltage based on the calculated frequency delta.

3. The processor of claim 2, wherein the CSC circuit is further configured to:
calculate a voltage delta between a target voltage and the supply voltage; and
increase the supply voltage based on both the calculated frequency delta and the calculated voltage delta.

4. The processor of claim 3, wherein the CSC circuit is configured to increase the supply voltage when the voltage delta is above a threshold.

5. The processor of claim 1, wherein the CSC circuit is configured to increase the supply voltage in a stepwise manner over a predetermined time period.

6. The processor of claim 1, further comprising:
a system management unit (SMU) configured to monitor the supply voltage and provide voltage telemetry data to the CSC circuit.

7. The processor of claim 6, wherein the predetermined sampling rate corresponds to a rate at which the SMU provides the voltage telemetry data to the CSC circuit.

8. A method for compensating clock stretch in a processor, comprising:
receiving voltage telemetry data indicating voltage droops in a supply voltage;
detecting, based on the voltage telemetry data, a reduction in an operating frequency by a digital frequency-locked loop (DFLL) circuit having a stretch response slope; and
increasing the supply voltage based on a difference between the operating frequency and a target frequency to counteract frequency reduction caused by the DFLL circuit's stretch response slope.

9. The method of claim 8, further comprising:
calculating a frequency delta between the target frequency and the operating frequency; and
increasing the supply voltage based on the calculated frequency delta.

10. The method of claim 9, further comprising:
calculating a voltage delta between a target voltage and the supply voltage; and
increasing the supply voltage based on both the calculated frequency delta and the calculated voltage delta.

11. The method of claim 10, wherein increasing the supply voltage occurs when the voltage delta is above a threshold.

12. The method of claim 8, wherein the voltage telemetry data is received from a system management unit (SMU) at a predetermined sampling rate.

13. The method of claim 12, wherein the predetermined sampling rate is one millisecond.

14. The method of claim 8, wherein the stretch response slope of the DFLL circuit is steeper than an adaptive voltage frequency scaling (AVFS) curve of the processor.

15. A clock stretch compensation (CSC) circuit for a processor, comprising:
a first input configured to receive voltage telemetry data from a system management unit (SMU);
a second input configured to receive frequency data indicating an operating frequency of a digital frequency-locked loop (DFLL) circuit; and
control logic configured to:
detect a reduction in the operating frequency caused by a stretch response of the DFLL circuit; and
output a control signal to increase a supply voltage based on the detected reduction.

16. The CSC circuit of claim 15, wherein:
the voltage telemetry data is received from the SMU at a predetermined sampling rate of one millisecond; and
the control signal is output at the predetermined sampling rate.

17. The CSC circuit of claim 15, wherein the control logic is further configured to:
calculate a frequency delta between a target frequency and the operating frequency; and
calculate a voltage delta between a target voltage and the supply voltage indicated by the voltage telemetry data.

18. The CSC circuit of claim 17, wherein the control logic is configured to:
output the control signal to increase the supply voltage when the voltage delta is above a threshold voltage value.

19. The CSC circuit of claim 15, wherein the control logic is configured to:
compare the operating frequency to an adaptive voltage frequency scaling (AVFS) curve; and
output the control signal to increase the supply voltage to bring the operating frequency closer to the AVFS curve.

20. The CSC circuit of claim 15, wherein the control logic is configured to continue outputting the control signal to increase the supply voltage until a maximum voltage threshold is reached.
